(19) United States
(12) Patent Application Publication
(10) Pub. No.: US 2021/0291068 A1
(43) Pub. Date: Sep. 23, 2021

(54) MODEL VEHICLE STATE DETECTION AND DETERMINATION METHOD AND SYSTEM

(71) Applicant: TRAXXAS, L.P., McKinney, TX (US)

(72) Inventors: Wesley R. Erhart, McKinney, TX (US); Brian Wan, Allen, TX (US); Scott Rollin Schmitz, Lewisville, TX (US); William Huang, McKinney, TX (US)

(73) Assignee: TRAXXAS, L.P., McKinney, TX (US)

(21) Appl. No.: 17/206,283

(22) Filed: Mar. 19, 2021

Related U.S. Application Data
(60) Provisional application No. 62/992,823, filed on Mar. 20, 2020.

(51) Int. Cl. A63H 30/04; G07C 5/04; A63H 17/32; A63H 17/28; A63H 17/34; G01R 19/165; G01R 19/10

(52) U.S. Cl. CPC A63H 30/04; G07C 5/04; A63H 17/32; G01R 19/10; A63H 17/34; G01R 19/1659; A63H 17/28

(57) ABSTRACT

A method of determining a state of a model vehicle using an electric motor is provided. During a sample period, the method may include measuring raw variables, including determining a first and a second voltage relative to a battery ground. Further, the method may include extracting state variables from the first and second voltages. The measuring of the raw variables may be repeated until the end of the sample period. The method may also include determining a tentative state from the state variables. Still further, the method may include setting a model vehicle state equal to a tentative state if the tentative state is equal to a previous tentative state. Still further including actuating a model vehicle component based upon the model vehicle state and setting the previous tentative state equal to the tentative state. Additionally, the method may include repeating the process for another sample period.

### RELATED APPLICATIONS

This application claims the benefit of a related U.S. Provisional Application Ser. No. 62/992,823 filed Mar. 20, 2020, entitled “MODEL VEHICLE STATE DETECTION AND DETERMINATION METHOD AND SYSTEM,” to Wesley R. ERHART, et al., the disclosure of which is incorporated by reference herein in its entirety.

### BACKGROUND

The following descriptions and examples are not admitted to be prior art by virtue of their inclusion in this section.

Radio Controlled (R/C) model vehicles have advanced along with the technology used to control and power them. Early hobby grade R/C model vehicles may have primarily been powered by nitro-fueled combustion engines. Many modern hobby grade R/C model vehicles are powered by brushed and brushless electric motors powered by advanced chemistry battery packs. One thing that has remained is the desire to more accurately and reliably reproduce the functions and appearance of full sized vehicles in the scale model environment of R/C model vehicles. However, size, space, and operational constraints often times inhibit the direct application of a full size vehicle solution from being applicable in a smaller, less complex scale version.

With the advent of Light Emitting Diodes (LEDs), scale lighting has become one of a number of popular accessories for to increase the realism of an R/C model vehicle. Headlights for example are a relatively simple application to replicate. The primary requirements for including functioning headlights are a power source and an on/off switch.

Brake and Reverse lights are more complicated to include. Since the same action with a remote transmitter can either function as braking or reverse (e.g., moving a throttle trigger past a neutral position and away from an operator), automated operation of these lights require an estimation or prediction of an R/C model vehicle state, i.e., braking, driven forward, driven reverse, neutral not moving, and neutral moving. Once these states are determined, brake and reverse lights may be implemented in a way that mimics full size vehicles. In addition, determination of the R/C model vehicle state may allow other optional accessories to be implemented, such as various appropriate engine, gear train, or warning sounds, driving figure animation, and other accessories depending upon application.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In accordance with an embodiment of this disclosure, a method of determining a state of a model vehicle using an electric motor is provided, wherein the electric motor may comprise either a brushed or a brushless motor. The method may include initializing variables, setting a sample time equal to zero, and starting a sample period comprising a sample period duration. In addition, the method may include measuring raw variables, including determining a first voltage relative to a battery ground and determining a second voltage relative to a battery ground. Further, the method may include extracting state variables from the first voltage and the second voltage and setting the sample time equal to the sample time plus an elapsed time.

Additional actions may also include returning to the action of the measuring of the raw variables if the sample time is less than or equal to the sample period and determining a tentative state from the state variables if the sample time is greater than the sample period duration. Still further, the method may include setting a model vehicle state equal to the tentative state if the tentative state is equal to a previous tentative state and actuating a model vehicle component based upon the model vehicle state and setting the previous tentative state equal to the tentative state. Additionally, the method may include returning to the action of the setting the sample time equal to zero.

In accordance with another embodiment of the current disclosure, a method of determining a state of a model vehicle using a brushless motor may be provided. The method may include initializing variables, setting a sample time equal to zero, and starting a sample period comprising a sample period duration. In addition, the method may include measuring raw variables, including determining a first voltage relative to a battery ground and determining a second voltage relative to a battery ground. Further, the method may include extracting state variables from the first voltage and the second voltage, setting the sample time equal to the sample time plus an elapsed time, and returning to the action of the measuring of the raw variables if the sample time is less than or equal to the sample period.

The method may also include determining a tentative state from the state variables if the sample time is greater than the sample period duration and setting a model vehicle state equal to the tentative state if the tentative state is equal to a previous tentative state and actuating a model vehicle component corresponding to the model vehicle state. In addition, the method may still further include setting a previous tentative state equal to the tentative state and returning to the action of the setting the sample time equal to zero.

In accordance with a still further additional embodiment of the current disclosure, a method of determining a state of a model vehicle using a brushed motor may be provided. The method may also include initializing variables, setting a sample time equal to zero, and starting a sample period comprising a sample period duration. Still further, the method may include measuring raw variables, which may comprise determining a first voltage relative to a battery ground and determining a second voltage relative to a battery ground. Also, the method may include extracting state variables from the first voltage and the second voltage, setting the sample time equal to the sample time plus an elapsed time, and returning to the action of the measuring of the raw variables if the sample time is less than or equal to the sample period.

Additionally, the method may still further include determining a tentative state from the state variables if the sample time is greater than the sample period duration, setting a model vehicle state equal to the tentative state if the tentative state is equal to a previous tentative state, and actuating a model vehicle component corresponding to the model vehicle state. Even further, the method may include setting the previous tentative state equal to the tentative state and returning to the action of the setting the sample time equal to zero.

Other or alternative features will become apparent from the following description, from the drawings, and from the claims.

### BRIEF DESCRIPTION OF THE DRAWINGS

Certain embodiments will hereafter be described with reference to the accompanying drawings, wherein like reference numerals denote like elements. It should be understood, however, that the accompanying drawings illustrate only the various implementations described herein and are not meant to limit the scope of various technologies described herein. The drawings are as follows:

FIG. 1 is a side view of a hand held transmitter, according to an embodiment of the current disclosure;

FIG. 2 is a schematic view of a state determination system for a brushed motor, according to an embodiment of the current disclosure;

FIG. 3 is a schematic view of a state determination system for a brushless motor, according to an embodiment of the current disclosure;

FIG. 4 is a flowchart showing a state determination system, according to an embodiment of the current disclosure;

FIG. 5 is an electrical schematic diagram of a raw measurement device, according to an embodiment of the current disclosure;

FIG. 6 is a table showing the relative voltages for a 6-step commutation brushless motor, according to an embodiment of the current disclosure;

FIG. 7 is a graph showing all three phase voltages vs. time for a driven brushless DC motor, according to an embodiment of the current disclosure;

FIG. 8 is a graph showing two phase voltages vs. time for a driven brushless DC motor, according to an embodiment of the current disclosure;

FIG. 9 is a graph showing two phase voltages vs. time in more detail than FIG. 8 for driven brushless DC motor, according to an embodiment of the current disclosure;

FIG. 10 is a graph showing all three phase voltages vs. time for a free spinning brushless DC motor producing a back EMF, according to an embodiment of the current disclosure;

FIG. 11 is a graph showing two phase voltages vs. time for a brushless DC motor going from a driven state to an idle state, according to an embodiment of the current disclosure;

FIG. 12 is a graph showing two phase voltages vs. time for a brushless DC motor going from an idle state to a braking state, according to an embodiment of the current disclosure;

FIG. 13 is a graph showing all three phase voltages vs. time for a brushless DC motor during braking (i.e., driven to zero), according to an embodiment of the current disclosure;

FIG. 14 is a graph showing two phase voltages vs. time for a brushless DC motor during braking when the motor is at a medium RPM, according to an embodiment of the current disclosure;

FIG. 15 is a graph showing two phase voltages vs. time for a brushless DC motor during braking when the motor is at a low RPM, according to an embodiment of the current disclosure;

FIG. 16 is a graph showing two phase voltages vs. time for a brushless DC motor during multiple states of the motor, according to an embodiment of the current disclosure; and

FIG. 17 is a flowchart showing an exemplary method for determining motor vehicle states, according to an embodiment of the current disclosure.

### DETAILED DESCRIPTION

In the following specification, numerous specific details are set forth to provide a thorough understanding of embodiments of the present disclosure. However, those skilled in the art will appreciate that the embodiments may be practiced without such specific details. In other instances, well-known elements have been illustrated in schematic or block diagram form in order not to obscure embodiments of the present disclosure in unnecessary detail. Some of the descriptions in the present disclosure refer to hardware components, but as those skilled in the art will appreciate, these hardware components may be used in conjunction with hardware-implemented software and/or computer software.

Reference throughout the specification to “one embodiment,” “an embodiment,” “some embodiments,” “one aspect,” “an aspect,” or “some aspects” means that a particular feature, structure, method, or characteristic described in connection with the embodiment or aspect is included in at least one embodiment of the present disclosure. Thus, the appearance of the phrases “in one embodiment” or “in an embodiment” or “in some embodiments” in various places throughout the specification are not necessarily all referring to the same embodiment. Furthermore, the particular features, structures, methods, or characteristics may be combined in any suitable manner in one or more embodiments.

Moreover, inventive aspects lie in less than all features of a single disclosed embodiment. Thus, the claims following the Detailed Description are hereby expressly incorporated into this Detailed Description, with each claim standing on its own as a separate embodiment.

Elements of the embodiments have been introduced with either the articles “a” or “an.” The articles are intended to mean that there are one or more of the elements. The terms “including” and “having” are intended to be inclusive such that there may be additional elements other than the elements listed. The term “or” when used with a list of at least two elements is intended to mean any element or combination of elements.

As described in the Background, determining the R/C model vehicle state may have multiple benefits. While in some cases, the model vehicle state may be directly determined from the throttle commands provided by a user operating a remotely located transmitter, prior generations and less complex versions of current R/C model vehicles may not be equipped to provide this direct indication of a model vehicle state. And yet users would still like to modify or customize their vehicles to have this ability.

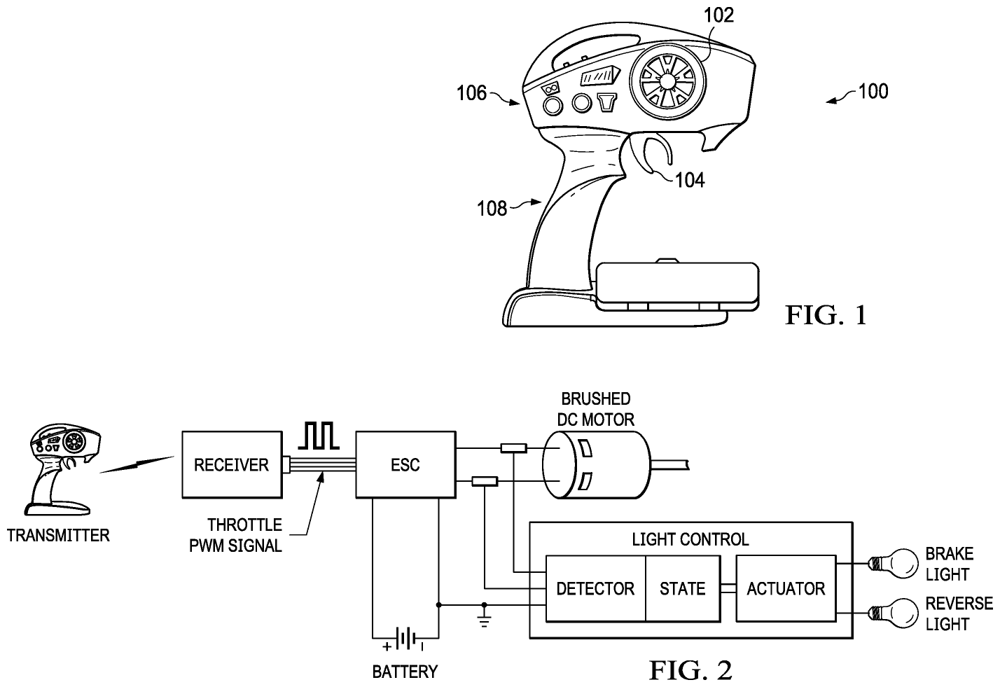

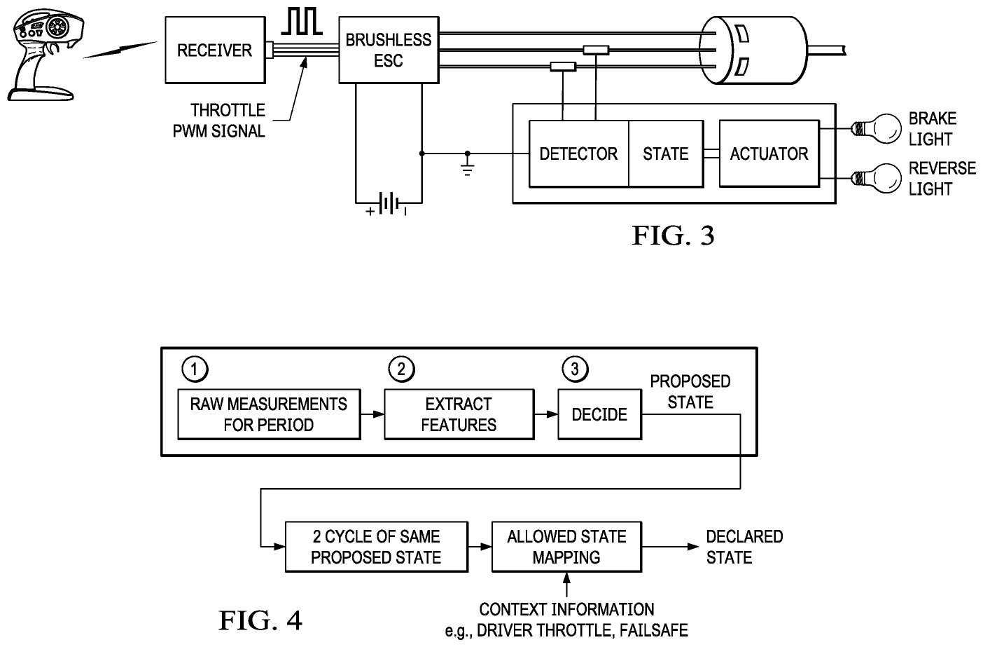

In general referring to FIG. 1, an embodiment of an R/C model vehicle system includes a remotely located, hand-held, user operated transmitter 100. This transmitter 100 may communicate with a vehicle mounted receiver (not shown in this figure) to apportion power from a battery pack to an electric motor (also not shown in this figure). Typically, the transmitter 100 will provide throttle commands via a throttle input 104 and steering commands via a steering input 102. The throttle commands and steering commands are electronically transmitted from the transmitter 100 via radio waves to the vehicle mounted receiver (see FIG. 2 for an example of a bushed motor system and FIG. 3 for an example of a brushless motor system).

However, the transmitter throttle input 104 generally comprises a finger operated pivoting lever that includes a neutral, forward, and reverse position. Unlike a full sized vehicle, there is no independent throttle pedal, brake pedal, or transmission lever to switch into either forward or reverse gears. Accordingly, the single throttle input 104 is configured to perform a variety of tasks depending upon whether or not the R/C model vehicle is currently moving and the direction in which the R/C model vehicle is currently moving.

The receiver may interpret these signals and actuates various servos to implement the throttle and steering commands. For example, the receiver may interpret the throttle commands and send a pulse width modulation (PWM) signal (for example in some embodiments) to a brushed or brushless Electronic Speed Control (ESC).

FIG. 2 generally illustrates an exemplary embodiment of a brushed motor ESC electronically coupled to both the battery pack and the brushed DC motor (BDC) via individual sets of two high current capacity wires. As further illustrated in this figure, the state determination device (labeled as Light Control) is electronically coupled to the first and second brushed DC motor power wires and the battery pack ground wire. The state determination device may be configured to read the raw voltages on the power wires and determine whether or not to actuate a brake or reverse light (among other possible actions, for example). The state determination device will be described in more detail at a later point.

A brushless DC motor (BLDC) is generally illustrated by the embodiment shown in FIG. 3. As with the brushed DC motor (BDC), the receiver in this embodiment may interpret the throttle command and send a signal such as a PWM signal (among other types and forms of signals) to a brushless ESC. The brushless ESC has three brushless motor power wires due to the requirements of the BLDC motor instead of two brushed motor power wires for the brushed ESC. However, the state determination device still connects to a first and a second brushless motor power wire and the battery back ground.

Embodiments of the state determination device for both a brushed and brushless ESC have some common elements. As shown in FIGS. 2 and 3, some embodiments of the state determination device comprises a detector, a state determination component, and an actuator. In these specific exemplary embodiments, the actuator is electrically coupled to a brake light and a reverse light and the actuator illuminates one or both depending upon a declared state (i.e., motor vehicle state) determined by the state determination component.

In some embodiments, the state determination device may additionally tap into or read the PWM signal sent by the receiver to the ESC. Included in the PWM signal is the receiver's conversion (interpretation, or translation) of the original throttle input 104 sent by the hand held transmitter 100.

The throttle input's 104 physical throttle position (PT) can vary from −1.0 (i.e., pushed fully forward, away from the handle 108, and representing either full reverse or full brake) to 0.0 (i.e., mid-position, neutral) to +1.0 (full pull, towards the handle 108, full forward). Since the throttle input 104 performs the functions of three individual components of a full sized vehicle, the following Table 1 illustrates what happens during a physical throttle position based on whether or not the R/C model vehicle is moving forward or reverse.

TABLE 1

| P_{T} | Vehicle Moving Forward | Vehicle Moving in Reverse |
|---|---|---|
| <0.0 | Forward Braking Action | Driven Reverse Throttle |
| 0.0 | Idle (no throttle, neutral position) | Idle (no throttle, neutral position) |
| | Vehicle may be coasting | Vehicle may be coasting in |
| | Forward | Reverse |
| >0.0 | Driven Forward Throttle | Reverse Braking Action |

As stated previously, the throttle position PT of the throttle input 104 and the equivalent electronic signal transmitted by the transmitter 100 that is interpreted by the receiver, may either be read directly from the signal (e.g., such as a PWM signal) sent by the receiver to the ESC, or read indirectly by referencing the voltage values detected by the state determination device measuring the raw voltage of a first and second brushed motor power wire or the raw voltages of a first and second brushless motor power wire and battery ground.

The brushed DC or BLDC motor may be determined to be in one of the following enumerated throttle command states:
Neutral—No Throttle Applied
Forward—Driven Forward
Reverse—Driven Reverse
Brake—Braking Motor

In addition, the R/C model vehicle may be determined to be in one of the following enumerated movement states:
Moving—The brushed DC or BLDC motor and R/C model vehicle are moving
Stationary or Still—The brushed DC or BLDC motor and the R/C model vehicle are both stationary (i.e., still or motionless)

In some embodiments, a motor RPM may be detected to measure or otherwise indicate the magnetic revolutions per minute (magnetic RPM) of a BLDC motor. For a 4 pole BLDC motor, the magnetic RPM is 2 times the physical RPM of the BLDC motor. In this situation, the physical motor RPM would be equivalent to the magnetic RPM/2.

However, in other embodiments of a state determination device, one or more of the previous states may not be realized. In some cases, the states may have different names and/or different enumerations or values. For example in a brushed DC motor, the magnetic RPM is equal to the physical RPM of the brushed DC motor. In this case, the physical motor RPM is equivalent to the magnetic RPM.

While in still other embodiments, the state determination device may use a single set of combined throttle command states and R/C model vehicle states. The combined vehicle system may have the following enumerated states:
Neutral Not Moving—No Throttle and the R/C model vehicle is stationary
Neutral Moving—No Throttle and the R/C model vehicle is in either forward or reverse motion. In some cases an engine brake may provide a slight retarding effect to the direction of motion
Brake—Braking Motor (i.e., in some cases, driving the motor voltage(s) to zero)
Forward—Driven Forward
Reverse—Driven Reverse

Embodiments of a state determination device may generally perform the following actions in order to actuate an optional accessory or component of an R/C model vehicle. Referring generally to FIG. 4, the state determination device performs raw measurements of an attribute for a predefined sample period. In the embodiments shown in FIGS. 2 and 3, this may involve measuring a first and second voltage from a first and second motor power wire. Features may be extracted from the sample period's raw measurements resulting in the determination of a tentative (i.e., proposed) state. While the R/C model vehicle is being operated, the raw measurements, feature extraction, determination of a tentative state may then repeat.

When two or more cycles of the same tentative state are repeated, then the tentative state is made a motor vehicle (i.e., declared) state and the optional accessory or component is actuated if appropriate. As the R/C model vehicle is being operated, the entire cycle may repeat as necessary until the R/C model vehicle is shut down.

In some embodiments, the motor vehicle state of the state determination device may depend in part on the previous motor vehicle state (i.e. previous proposed state). And while repeats of two or more cycles of the same tentative state are described as having to occur before determining a motor vehicle state, this is to try and dampen the potential actuation response and prevent transitory or temporary actuations of the optional accessories or components.

For example, a flickering brake or reverse light could confuse the user. Two, or more than two as appropriate, repeats of the proposed or tentative state may be used in order to decrease or diminish the transitory effects resulting from a small sample period. In some cases, if the sample period is long enough, it may be appropriate to use a single tentative state to determine a motor vehicle state and actuate an optional accessory or component. While in still other cases, it may be more appropriate to have three or more repeated tentative states prior to determining a motor vehicle state.

In other embodiments, the various actions or orders of the actions shown in FIG. 4 may change or be different depending upon the requirements of a particular motor vehicle state. For example, the motor RPM state may be determined by instituting a tracking loop in addition to the action of extracting the features from the raw measurements.

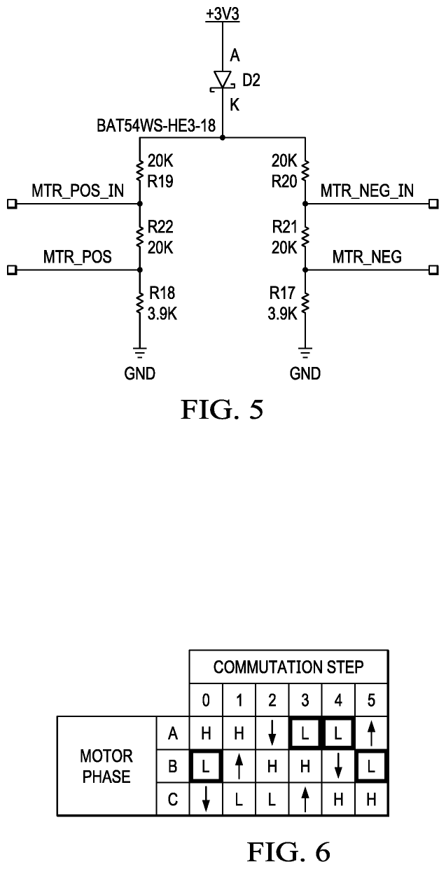

Referring now to FIG. 5, an embodiment of the state determination device may determine the raw measurements using the illustrated schematic diagram. The values and exact configuration are only exemplary and a person of skill in the art would be able to adapt the wire schematic to their individual application. In this exemplary illustration, MTR_POS_IN and MTR_NEG_IN are electrically connected to a first and second motor power wire. The MTR_POS and MTR_NEG are the state determination device's detector measurement of the raw measurements, in this case, a first and second raw voltage.

The raw measurements are determined for a predefined period of time, herein referred to as a sample window, at a fixed sample rate. For example, in one embodiment, a 50 msec window may determine approximately 125,000 samples/sec before moving to feature extraction to determine the tentative state. Of course, different embodiments may use different sampling window sizes, different sampling rates, digital windowing functions (e.g., such as a Blackman window) and even overlapping windows.

While still other embodiments may include other measurements. For example, in one situation, the state determination device may measure the motor current in order to estimate the motor's load state. A sound module may then be actuated corresponding with the load state to generate realistic simulated motor sounds.

The state determination device may extract the features by processing the raw measurements useful for a tentative state determination. The features that are selected may include summary statistics robust to noise such as averages or counts. For the purpose of this description, noise refers to any signal upsetting the determination of the R/C model vehicle's state. For example, when a high-current six step commutated BLDC motor's high phase switches to floating, the phase presents a voltage measurement under battery ground. According to a state determination device, this phase may appear to be driven low. In this embodiment, the value would be considered as noise.

In this descriptive embodiment, some features are selected due to the reason that they have a small computational cost, such as counts focusing on determining the motor vehicle states useful for actuation and illumination of a brake and/or reverse light. However, feature extractions requiring an additional computational load such as a 50 msec Fourier Transform (i.e., Spectrogram) in order to determine the motor RPM over time, ESC-Motor warning tones, “cogging” count, or motor health are not precluded from embodiments within the scope of the current disclosure.

Feature selection (i.e., which features to extract) may be part of an iterative design process in which various features are tried and the detection success rates are compared. The process of feature selection should not require undue or excessive testing but is instead, part of a normal process of optimizing a state determination device inherent in the adaptation of any application.

A tentative state is the result of evaluating the features against a set of decision boundaries. In some embodiments, the decision boundaries may be as simple as a series of feature comparisons or determined through a logistic regression or clustering technique. For specific ESC and brushed DC or BLDC motor combinations, determining a motor vehicle state for brake and reverse light actuation may be accomplished via simple comparisons. However, more robust decision boundaries may be determined by minimizing a cost (e.g., such as an error) function of many identified ESC-motor labeled data sets.

In the case of a brake and reverse light actuation, the illumination of the individual lights needs to be predictable and robust. For a motor vehicle state, in view of an exemplary detection latency of under 150 msec, a hysteresis is added in order to reduce or minimize light flicker. For other features, a hysteresis may not be needed or necessary. For example, a hysteresis may be skipped for other state determinations such as motor RPM.

The tentative state is identified as a motor vehicle state through the functioning of the state determination device's detector and actuator. In some embodiments, the tentative state may be mapped into the motor vehicle state while taking advantage of additional contextual information outside of the motor states.

For example, the state determination device may consider the previous motor vehicle states. When the motor vehicle state transitions from Driven Reverse to Brake, the actuator of the state determination device may maintain the actuation of the reverse light and add the actuation of the reverse light. The R/C model vehicle in this situation would be coasting in reverse after having received a reverse throttle command, and while coasting, a braking force is applied.

In some embodiments in which the throttle input 104 is measured, if the previous situation is both a reverse and brake light illumination, then moving the throttle input 104 to a neutral position would extinguish the brake light and yet keep the reverse light illuminated. Once the R/C model vehicle stops coasting in reverse, either through friction or with the aid of a slight amount of motor braking (which would fall below a level necessary to illuminate the brake light), then the reverse light would be extinguished. This embodiment is configured to mimic the behavior of a full sized vehicle scenario in which a driver starts the vehicle going in reverse and then applies a braking force during the reversing motion of the vehicle.

In other embodiments, additional information such as the throttle input 104 may be used to make a motor vehicle state more realistic for an R/C model vehicle user. As briefly mentioned, some ESC's may be equipped to provide a ‘drag brake’ function. With this function, the ESC may apply a small amount of braking force when the throttle input 104 is in a neutral position or when an R/C model vehicle is coasting in either the forward or reverse direction. The small amount of braking force simulates the full sized vehicle's transmission or engine drag. However, even though this is a braking force, the state determination device may not actually actuate the brake lights. In some cases by measuring the throttle input position 104, measuring the level of braking force, or measuring back Electro-Motive Force (EMF) via the raw voltage measurements, the state determination device may not actuate the brake light as a result of a drag braking effect.

The following embodiment of the current disclosure will describe feature extraction using a brushed DC motor. In this embodiment, the sample rate is 64 ksamples/sec and the state determination device reads a first and second voltage via a first and second brushed motor power wire. Using a sampling window of 10 msec of raw measurements, some exemplary features may be illustrated in the following Table 2.

TABLE 2

| | Feature | |
|---|---|---|
| | Formula (N | |
| | is a number | |
| Feature | of samples) | Description |
| ave V_{Δ} | 1/N Σ V_{A} − | Average of the brushed motor power wire voltage |
| | V_{B} | difference |
| min V_{Δ} | min V_{A} − V_{B} | Minimum voltage difference |
| max V_{Δ} | max V_{A} − V_{B} | Maximum voltage difference |
| ave V_{A} | 1/N Σ V_{A} | Average of first brushed motor power wire voltage |
| min V_{A} | min V_{A} | Minimum of first brushed motor power wire |
| | | voltage |
| max V_{A} | max V_{A} | Maximum of first brushed motor power wire |
| | | voltage |
| ave V_{B} | 1/N Σ V_{B} | Average of second brushed motor power wire |
| | | voltage |
| min V_{B} | min V_{B} | Minimum of second brushed motor power wire |
| | | voltage |
| max V_{B} | max V_{B} | Maximum of second brushed motor power wire |
| | | voltage |
| V_{App} | Max V_{A} − | Voltage peak to peak of first brushed motor wire |
| | min V_{A} | voltage |
| V_{App} | Max V_{B} − | Voltage peak to peak of second brushed motor wire |
| | min V_{B} | voltage |

Any number of statistical techniques may be used to determine the relative likelihood of a tentative state determination. In an embodiment of the brushed DC motor, a simple “if-check” sequence was found to be sufficient. If the next proposed state is consistent for 4 feature sets (i.e., 40 msec according to the 10 msec sampling window), a new declared state is determined.

An illustrative example of the if sequence in pseudo code in which the tentative state is referred to as a proposed state is:

if low speed/idle braking:
proposed state is BRAKE
else if neutral detection (not moving):
proposed state is neutral (not moving)
else if forward motion detection:
proposed state is forward motion
else if reverse motion detection:
proposed state is reverse
else if normal brake detection:
proposed state is brake

The detected motor vehicle state is determined by comparing the extracted features to various thresholds. The thresholds in this illustrative embodiment were determined experimentally. Generally, the thresholds were determined by using labeled data and adjusting the thresholds to minimize any error rate. In other embodiments, further statistical techniques such as clustering or logistic regression could be use. However, still another option is to iterate the extracted features.

Extracted feature selection and decision boundary determination may be an iterative process with some standard experimentation. Referring again to a brushed DC motor using an embodiment of a state determination device, a data mining style process is initially used. The first and second voltages are determined from measurements from a brushed ESC, a set of features is determined, and the feature space is split according to decision boundaries. To minimize the state determination device's cost, both the computational and memory cost of the extracted features may be reduced and minimized.

In some embodiments of this disclosure, feature and decision boundary development may be gathered using Saleae logic. Sample data will be described later. For brushed DC motor refinement, Saleae logic may be used to capture the brushed motor power wire's first and second voltages. The system may be placed in different states and the Saleae logic capture triggered. The presented set of features and decision boundaries may then be determined via examination of the waveform in the Saleae logic user interface.

The following Table 3 illustrates exemplary experimental feature extraction for a 12 turn brushed DC motor. Each feature may be normalized by the total number of counts N.

TABLE 3

| | Feature Formula (N is | |
|---|---|---|
| | the number of samples, | |
| Feature | Δ is the time difference) | Description |
| N | N | Count of the Samples |
| Fwd | \|(Va − Vb) > Threshold_{Positive}\| | Count of Positive applied |
| | | voltage |
| Rev | \|(Va − Vb) < Threshold_{Negative}\| | Count of Negative applied |
| | | voltage |
| Idle | \|Threshold_{IdleLow} < Va,Vb < | Count of voltages in an Idle |
| | Threshold_{IdleHigh}\| | range |
| Brake | \|Va < Threshold_{Low}&Vb < | Count of both Voltages being |
| | Threshold_{Low}\| | pulled to ground |

Table 4 below illustrates the exemplary decision boundaries determined for the experiment using the brushed DC motor.

TABLE 4

| | | Decision Boundary |
|---|---|---|
| Order | Declared State | Description Applied in Order |
| 1 | Neutral | Idle > Threshold_{Idle} |
| | (not moving) | |
| 2 | Driven | (Fwd − Threshold_{Window}) > max (Rev, Brake, |
| | Forward | Idle) |
| 3 | Driven | (Rev − Threshold_{Window}) > max (Fwd, Brake, |
| | Reverse | Idle) |
| 4 | Brake | (Brake − Threshold_{Window}) > max (Fwd, Rev, |
| | | Idle) |

For a BLDC motor embodiment refinement, Saleae logic may be used to capture the brushless motor power wire's first and second voltages. A Saleae application can then be used to export the data to comma separated value (csv) files. Similarly, Saleae logic may be used to capture the state determination device's detector's measurement of Phase A (MTR_POS) and Phase B (MTR_NEG) brushless motor wires between the ESC and the brushless motor. The Saleae exported csv files can provide rows containing the measurement time, Phase A's voltage (V_{A}), and Phase B's voltage (V_{B}).

For a 6-step commutation brushless motor, several Pulse Width Modulation (PWM) strategies may be used to power the motor. In some cases, an ESC may pulse the high phase and continuously drive the low phase to ground. However, in other cases, the ESC may pulse the low phase to ground and continuously drive the high phase to battery positive. The 6-step commutation contains 6-steps. The experimental data used for this disclosure had an ESC that pulsed the low phase to ground and continuously drove the high phase to battery positive.

As an ESC progresses the brushless motor through all 6-steps, the relative voltages between the phases change in sequence. This relationship holds for the idle case as well. As shown in Table 5:

TABLE 5

| Step | Voltage Relationship |
|---|---|
| 0 | V_{A} > V_{C} > V_{B} |
| 1 | V_{A} > V_{B} > V_{C} |
| 2 | V_{B} > V_{A} > V_{C} |
| 3 | V_{B} > V_{C} > V_{A} |
| 4 | V_{C} > V_{B} > V_{A} |
| 5 | V_{C} > V_{A} > V_{B} |

Referring generally to FIG. 6, this figure enumerates the state of each phase during each commutation step. The low phase steps for the A and B phases are highlighted with an extra box drawn around the L (i.e., the Low Phase). The arrows represent either falling or rising voltages as the steps go from 0 to 5 and then repeat, i.e., from left to right as seen in the table. This holds true as the BLDC motor continues to rotate in this direction.

When the BLDC motor is rotating in an opposite or a reverse direction as compared to the rotation described in the table (i.e., from right to left, steps 5 to 0 and then repeat) the arrows change to their opposing values (i.e., a rising arrow becomes a falling arrow and a falling arrow becomes a rising arrow). The experimental embodiment of the state determination device monitored two phases, the A phase and the B phase.

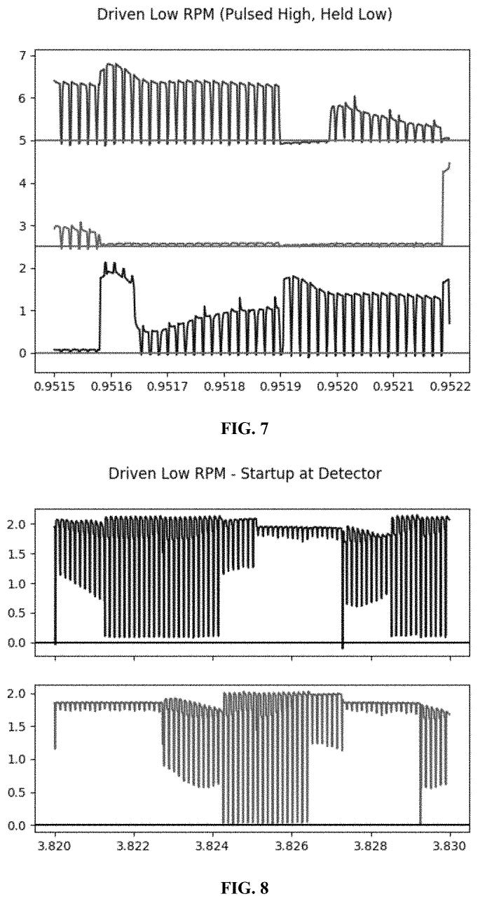

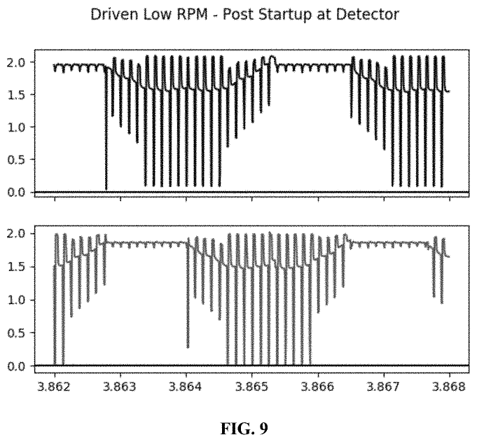

Turning now to FIG. 7, this figure illustrates experimental phase voltages of a driven BLDC motor. The three graphs capture all three phase voltages during the same time range from the BLDC motor. As determined from FIG. 6, the phases are going from right to left, starting at Step 0 and then transitioning directly to Step 5. The arrows are in the reverse orientation from the ones shown in FIG. 6. As shown in this graph, the three phase voltages are captured when an ESC pulses the high phase and holds the low phase to battery negative.

Referring generally to FIGS. 8 and 9, these graphs represent the raw voltage captures of two phases of a driven BLDC motor. In this case, the BLDC motor is being driven in the opposite rotational direction than the rotational direction shown in FIG. 7. This rotational direction is the same as the direction used to produce the chart in FIG. 6, which is read left to right. The graphs represents a BLDC motor starting at approximately Step 2 going to the right through Step 5 and then from Step 0 to approximately Step 4 by the end of the graph. The data shown is from a time period in which the ESC holds the high phase to battery voltage and pulses the low phase to ground.

FIG. 9 represents a closer look at data from the BLDC motor being driven in the same direction as FIG. 8, but at a slightly later time stamp and slightly increased resolution. In this figure, the BLDC motor starts at approximately Step 1 and goes to Step 5 and then from Step 0 to approximately Step 4, reading left to right. The total time scale of FIG. 9 is approximately 0.006 seconds while the total time scale of FIG. 8 is approximately 0.010 seconds.

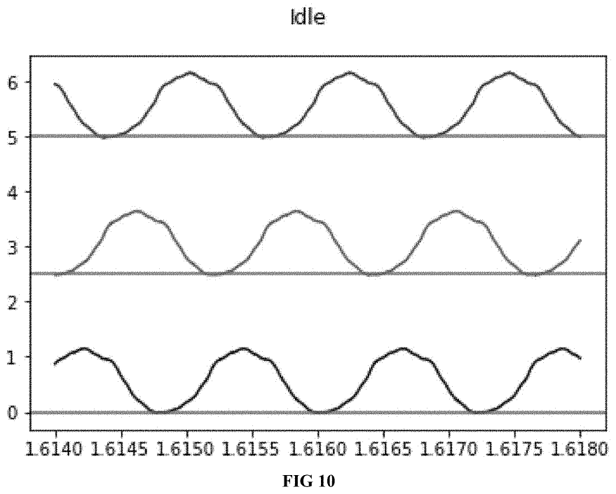

FIG. 10 is an illustration of the phase voltages of a free spinning motor (not being driven by an ESC) that is producing a back ElectroMotive Force (EMF). The BLDC motor is in an idle state and not driven forward or reverse, but still rotating. Since the back EMF is being produced, the R/C model vehicle is still in motion from the last throttle command, i.e., coasting from either being driven forward or driven reverse. At any moment in time, the voltages of the various phases are not equal to one another. This may be represented by:

0≤V_{A}≠V_{B}≠V_{C}≤V_{Battery}

The sequence of the back EMF follows the same sequence as the previously driven state.

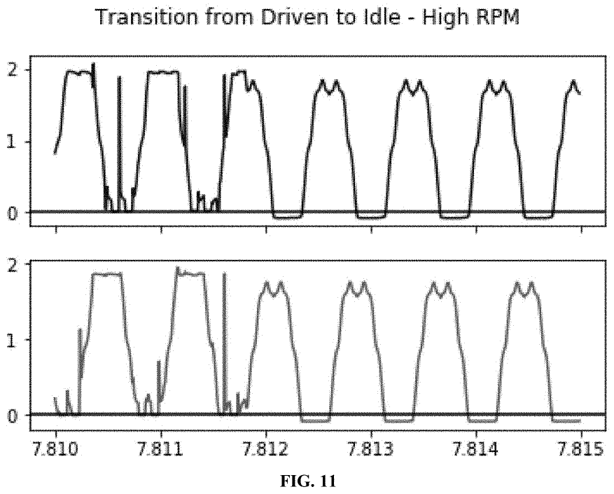

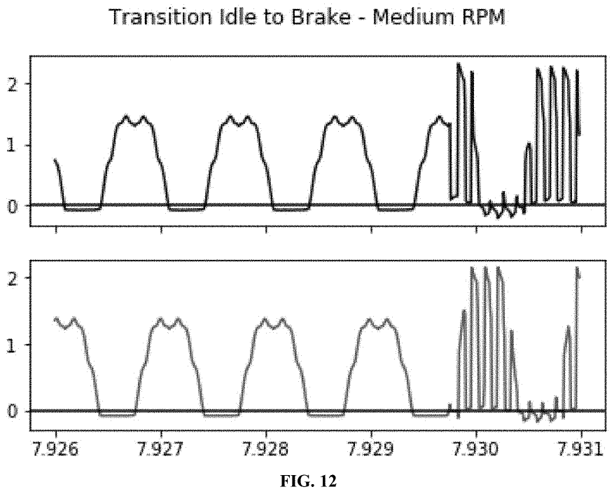

In FIGS. 11 and 12, the phase A and phase B measurements at the state determination device's detector are shown as the BLDC motor transitions from being driven to idle and from idle to braking, respectively. In FIG. 11, the BLDC motor is driven until approximately the last third of the interval beginning at 7.811, and then switches to idle but moving (i.e., a free spinning BLDC motor due to the coasting of an R/C model vehicle, for example). In FIG. 12, the BLDC motor transitions from an idle but moving state to a braking condition at approximately the last quarter of the interval beginning at 7.929. These two figures represent data values when there is no added drag braking effect.

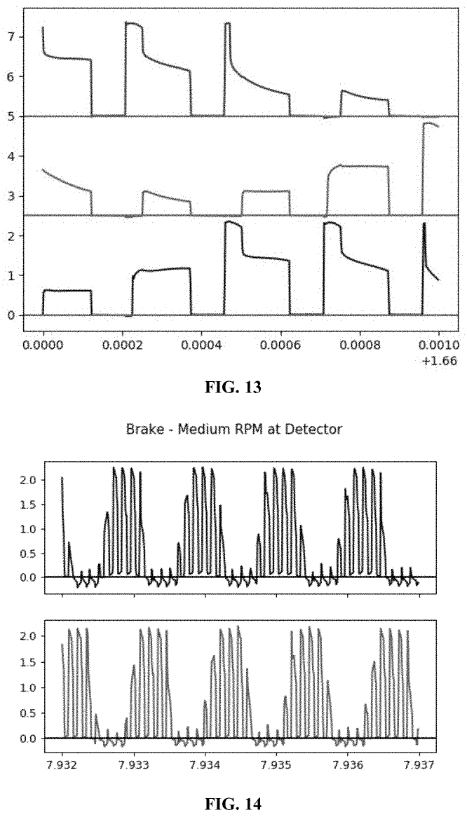

The next three figures, FIG. 13-15, illustrate phase voltage conditions in which the BLDC motor is braking. During a braking action, all of the voltages for the various phases are pulled to zero during the same pulses. As illustrated below:

V_{A}=V_{B}=V_{C}=0

When the BLDC motor is not pulsed low, the phase voltages may follow the idle state until the R/C model vehicle is stationary.

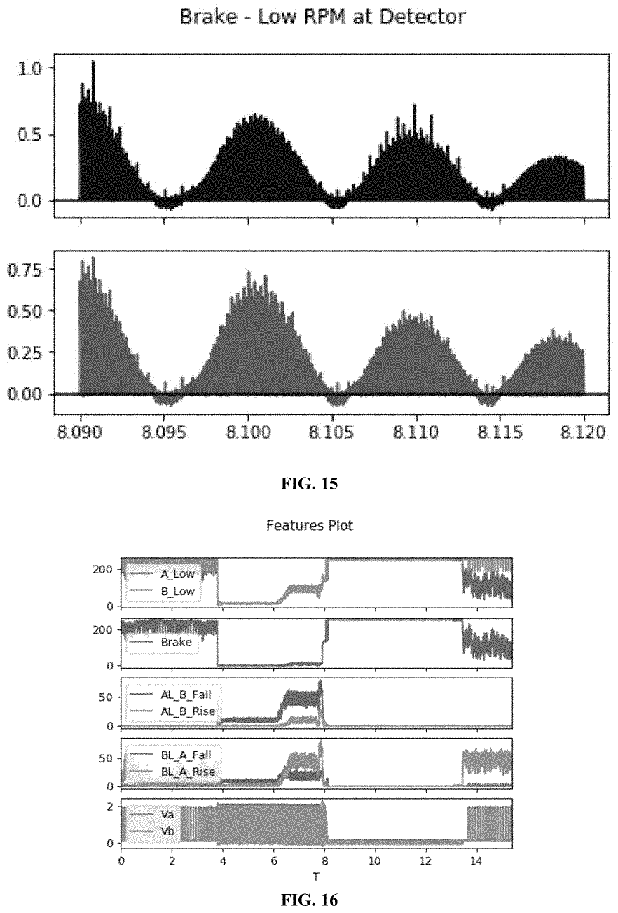

As with FIG. 10 showing all three voltages during an idle state, FIG. 13 also illustrates all three voltages. However, in this case the various phase voltages of FIG. 13 are being pulsed to zero at the same time. The pulsing to zero occurs during the braking pulses. FIG. 14 illustrates two detected phase voltages during braking pulses at a medium RPM as seen by the state determination device's detector. FIG. 15 illustrates the same pulsing to zero but shown over a longer period of time.

In order to determine the raw measurements of the experimental embodiment of the BLDC motor state determination device, the detector was electrically coupled with phase A and phase B of the BLDC motor power wires. V_{A} and V_{B} were then sampled at 125 kHz over 50 msec sampling windows. The feature extraction for each window is illustrated in Table 6 below.

TABLE 6

| | Feature Formula (N is the | |
|---|---|---|
| | number of Samples, Δ is the | |
| Feature | time difference) | Description |
| N | N | Count of the Samples |
| A_{Low} | \|V_{A} < Threshold_{Low}\| | Count of V_{A} samples that are Low |
| B_{Low} | \|V_{B} < Threshold_{Low}\| | Count of V_{B} samples that are Low |
| Brake | \|V_{B} < Threshold_{Low} & | Count of V_{A} and V_{B} samples that are Low |
| | V_{A} < Threshold_{Low}\| | |
| A_{Low} − B_{Fall} | \|V_{A} < Threshold_{Low} & ΔV_{B} < 0\| | Count of V_{B} falling when V_{A} is low |
| | \|V_{A} < Threshold_{Low} & ΔV_{B} > 0\| | Count of V_{B} rising when V_{A} is low |
| B_{Low} − A_{Fall} | \|V_{B} < Threshold_{Low} & ΔV_{A} < 0\| | Count of V_{A} falling when V_{B} is low |
| B_{Low} − A_{Rise} | \|V_{B} < Threshold_{Low} & ΔV_{A} > 0\| | Count of V_{A} rising when V_{B} is low |

In the table, ΔV_{A}=V_{A}[t]−V_{A}[t−1]. ΔV_{B} is determined similarly as well. The Threshold_{Low} in this experimental embodiment was 0.12 volts. However, actual voltage thresholds may vary according to their specific application. In addition, A_{Low}-B_{Fall} and B_{Low}-A_{Rise} represent one direction of rotation for a BLDC motor corresponding to differences in connecting to two of the BLDC motor power wires, and A_{Low}-B_{Rise} and B_{Low}-A_{Fall} represent the opposite direction for the same corresponding BLDC motor power wire connections.

Referring generally to FIG. 16, this figure illustrates a sample of data values for multiple states of a BLDC motor. In the top graph, the A_{Low} and B_{Low} values track closely to one another until the last portion of the graph (i.e., approximately 13.5 and 14), when A_{Low} separates out below B_{Low}. The second highest graph is only Brake. The middle graph has AL_B_Fall above AL_B_Rise between 6 and 8. The second from the bottom graph has BL_A_Fall relatively consistent while BL_A_Rise is above between 6 to 8 seconds and 14 seconds onward. The bottommost graph shows the two voltages track approximately together.

The decision boundaries for a BLDC motor were experimentally determined for the experimental embodiment and are shown in Table 7 below.

TABLE 7

| Order | State | Decision Boundary Description Applied in Order |
|---|---|---|
| 0 | Neutral (not | abs (Brake − A_{Low}) < Threshold_{Moving}) & |
| | moving) | abs (Brake − B_{Low}) < Threshold_{Moving}) |
| 1 | Brake | Brake ≥ A_{Low}/2 |
| 2 | Driven | (A_{Low}B_{Fall} > A_{Low}B_{Rise}) & (B_{Low}A_{Rise} < |
| | Forward | B_{Low}A_{Fall}) |
| 3 | Driven | (B_{Low}A_{Fall} > B_{Low}A_{Rise}) & (A_{Low}B_{Rise} > |
| | Reverse | A_{Low}B_{Fall}) |

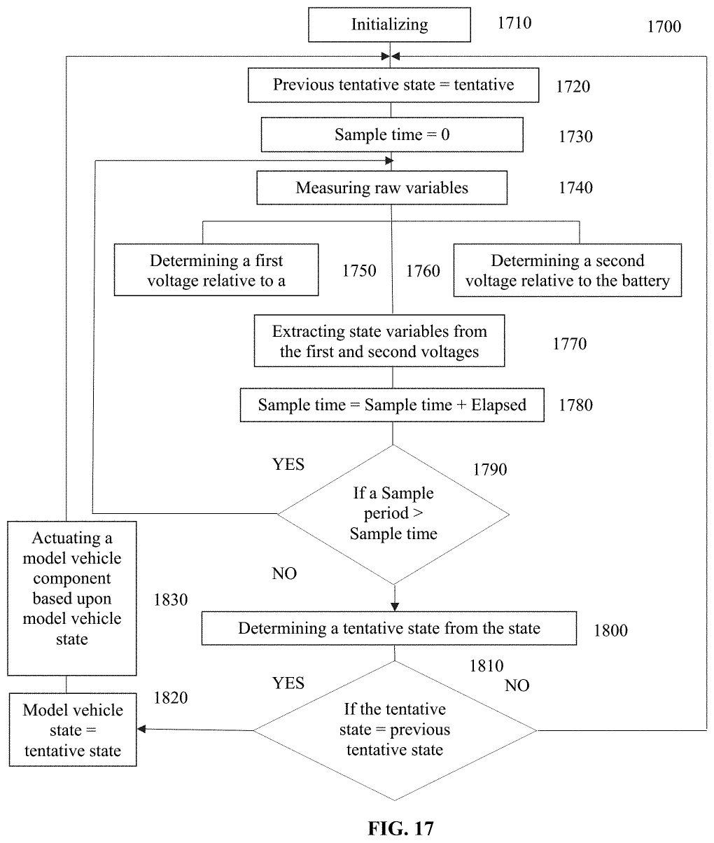

One embodiment of a model vehicle state detection method 1700 is shown in FIG. 17. The method includes initializing variables 1710 and setting a previous tentative state equal to a tentative state 1720. Another action is setting a sample time equal to zero 1730.

At this point, actions that are repeated throughout the period are performed. One action includes measuring raw variables 1740, which involves determining a first voltage relative to a battery ground 1750 and determining a second voltage relative to the battery ground 1760. Once the raw voltages are obtained, the method involves extracting state variables from the first voltage and the second voltage 1770, setting the sample time equal to the sample time+an elapsed time 1780, and returning to or restarting at the action of the measuring of the raw variables if a sample period duration is greater than the sample time 1790. However, if the sample time is less than or equal to a sample period duration, the method includes determining a tentative state from the state variables 1800.

In addition, the method involves setting a model vehicle state equal to the tentative state 1820 if the tentative state is equal to a previous tentative state 1810. Please note that this is only an example to dampen the response of the mode vehicle component. Depending upon the application, the model vehicle state may require the tentative state to be equal to the previous two, three, or more previous tentative dates. Once this is met, the method includes actuating a model vehicle component based upon the model vehicle state 1830.

The method then includes returning or restarting the method at the action of setting the previous tentative state equal to the tentative state 1720 and setting the sample time equal to zero 1730. Each of the various actions will be described in more detail as follows.

Initializing the variables includes setting a previous model vehicle state equal to a neutral state, setting the previous tentative state equal to the neutral state, and setting brake equal to zero. These actions are performed regardless of the type of electric motor, brushless or brushed.

However, when the electric motor is a brushless motor, the initializing variables action further includes setting a previous first voltage equal to zero and setting a previous second voltage equal to zero. In addition, the action further includes setting A_{Low}, B_{Low}, A_{Low_}B_{Fall}, A_{Low_}B_{Rise}, B_{Low_}A_{Fall}, and B_{Low_}A_{Rise}, all equal to zero. For a brushed motor, the actions alternatively include setting N, Fwd, Rev, and Idle all equal to zero.

For brushless electric motors, extracting state variables from the first voltage and the second voltage may include setting the A_{Low}=the A_{Low}+1 if the first voltage is less than a Threshold_{Low}, setting the B_{Low}=the B_{Low}+1 if the second voltage is less than the Threshold_{Low}, and setting the brake=the brake+1 if the first voltage is less than the Threshold_{Low} and the second voltage is less than the Threshold_{Low}. In addition, extracting state variables may include setting the A_{Low_}B_{Fall}=the A_{Low_}B_{Fall}+1 if the first voltage is less that the Threshold_{Low} and the second voltage−the previous second voltage is less than or equal to zero, and setting the A_{Low_}B_{Rise}=the A_{Low_}B_{Rise}+1 if the first voltage is less that the Threshold_{Low} and the second voltage−the previous second voltage is greater than zero.

Extracting state variables my further include setting the B_{Low_}A_{Fall}=the B_{Low_}A_{Fall}+1 if the second voltage is less that the Threshold_{Low} and the first voltage−the previous first voltage is less than or equal to zero, and setting the B_{Low_}A_{Rise}=the B_{Low_}A_{Rise}+1 if the second voltage is less that the Threshold_{Low} and the first voltage−the previous first voltage is greater than zero. Still further, extracting state variables may include setting the previous first voltage equal to the first voltage, and setting the previous second voltage equal to the second voltage.

For brushed electric motors, extracting state variables from the first voltage and the second voltage may include setting the N=the N+1, setting the Fwd=the Fwd +1 if the first voltage minus the second voltage is greater than or equal to a Threshold_{Positive}, and setting the Rev=the Rev+1 if the first voltage minus the second voltage is greater than or equal to a Threshold_{Negative}. In addition, extracting state variables may include setting the Idle=the Idle+1 if the first voltage and the second voltage are within a range of a Threshold_{IdleLow} and a Threshold_{IdleHigh}, and setting the brake=the brake+1 if the first voltage is less than a Threshold_{Low} and the second voltage is less than the Threshold_{Low}.

For brushless electric motors, determining the tentative state may include setting a tentative state equal to the neutral state if the brake is less than or equal to a Threshold_{Brake} and the A_{Low_}B_{Fall} and the A_{Low_}B_{Rise} and the B_{Low_}A_{Fall} and the B_{Low_}A_{Rise} are each lower than a Threshold_{Move}, setting the tentative state equal to a brake state if the brake is greater than the Threshold_{Brake}, and setting the tentative state equal to a forward state if the A_{Low_}B_{Fall} is greater than both the A_{Low_}B_{Rise} and the Threshold_{Move} or if the B_{Low_}A_{Fall} is greater than both the B_{Low_}A_{Rise} and the Threshold_{Move}.

In addition, determining the tentative state may include setting the tentative state equal to a reverse state if the A_{Low_}B_{Rise} is greater than both the A_{Low_}B_{Fall} and the Threshold_{Move} or if the B_{Low_}A_{Rise} is greater than both the B_{Low_}A_{Fall} and the Threshold_{Move}, setting the tentative state equal to a neutral moving state if the first and the second voltages are each greater than the Threshold_{Move} and the first voltage is not equal to the second voltage, and setting the previous tentative state equal to the tentative state;

For brushed electric motors, determining the tentative state may include normalizing the Fwd, the Rev, the Idle, and the brake by dividing each of them by the N, respectively providing normalized Fwd, normalized Rev, normalized Idle, and normalized Brake, and setting the tentative state equal to the neutral state if the normalized Idle is greater than a Threshold_{Idle}. In addition, determining the tentative state may involve setting the tentative state equal to the forward state if the normalized Fwd is greater than a maximum of each of the normalized Rev, the normalized brake, and the normalized Idle, and setting the tentative state equal to the reverse state if the normalized Rev is greater than a maximum of each of the normalized Fwd, the normalized brake, and the normalized Idle.

Actuating a model vehicle component may include activating and deactivating various model vehicle components, such as illuminating and extinguishing brake and reverse lights, among other things. In some embodiments, an actuation marker will record and identify activated components or indicate when no model vehicle components are to be activated. For example, the actuation marker may include off, brake illuminated, reverse illuminated, brake and reverse illuminated, or others values as appropriate for an application.

When the model vehicle state is equal to the brake state and an actuation marker is equal to off or reverse illuminated, then the brake light as the model vehicle component is illuminated or activated. In some instances, an operator may command a braking action while coasting in reverse, requiring both the brake and reverse lights to become illuminated.

If the action is illuminating a brake light when the actuator marker is off, the actuator marker is set to brake illuminated. If the action is illuminating a brake light when the actuator marker is set to reverse illuminated, then the actuator marker is set to brake and reverse illuminated. When the model vehicle state is equal to reverse and the actuator marker is equal to off, the reverse light, as the model vehicle component, is activated or illuminated and the actuator marker is equal to reverse illuminated.

If the model vehicle state is equal to the neutral state or the forward state and the actuator marker is equal to brake illuminated, then the brake light is extinguished or deactivated and the actuator marker is set to off. If the model vehicle state is equal to the neutral state or the forward state and the actuator marker is equal to reverse illuminated, then the reverse light is extinguished or deactivated and the actuator marker is set to off. If the model vehicle state is equal to the neutral state or the forward state and the actuator marker is equal to brake and reverse illuminated, then the brake light and the reverse light are extinguished or deactivated and the actuator marker is set to off.

In the claims, means-plus-function clauses are intended to cover the structures described herein as performing the recited function and not only structural equivalents, but also equivalent structures. Thus, although a nail and a screw may not be structural equivalents in that a nail employs a cylindrical surface to secure wooden parts together, whereas a screw employs a helical surface, in the environment of fastening wooden parts, a nail and a screw may be equivalent structures.

It is the express intention of the applicant not to invoke 35 U.S.C. § 112, paragraph 6 for any limitations of any of the claims herein, except for those in which the claim expressly uses the words ‘means for’ together with an associated function.

What is claimed is:

1. A method of determining a state of a model vehicle using an electric motor, wherein the electric motor comprises a brushed motor or a brushless motor, comprising:
initializing variables;
setting the previous tentative state equal to the tentative state;
setting a sample time equal to zero;
measuring raw variables comprising:
determining a first voltage relative to a battery ground; and
determining a second voltage relative to the battery ground;
extracting state variables from the first voltage and the second voltage;
setting the sample time equal to the sample time+an elapsed time;
returning to the action of the measuring of the raw variables if a sample period duration is greater than the sample time;
determining a tentative state from the state variables if the sample time is greater than the sample period duration;
setting a model vehicle state equal to the tentative state if the tentative state is equal to a previous tentative state and actuating a model vehicle component based upon the model vehicle state; and
returning to the action of the setting the previous tentative state equal to the tentative state.

2. The method according to claim 1, wherein the initializing variables action comprises:
setting a previous model vehicle state equal to a neutral state.
setting the previous tentative state equal to the neutral state;
setting brake equal to zero;
wherein when the electric motor is the brushless motor, the initializing variables action further comprises:
setting a previous first voltage equal to zero;
setting a previous second voltage equal to zero;
setting A_{Low} equal to zero;
setting B_{Low} equal to zero;
setting A_{Low_}B_{Fall} equal to zero;
setting A_{Low_}B_{Rise} equal to zero;
setting B_{Low_}A_{Fall} equal to zero; and
setting B_{Low_}A_{Rise} equal to zero;
wherein when the electric motor is the brushed motor, the initializing variables action further comprises:
setting N equal to zero;
setting Fwd equal to zero;
setting Rev equal to zero; and
setting Idle equal to zero.

3. The method according to claim 2, wherein the extracting state variables from the first voltage and the second voltage comprises:
wherein when the electric motor is the brushless motor, the extracting state variables from the first voltage and the second voltage further comprises:
setting the A_{Low}=the A_{Low}+1 if the first voltage is less than a Threshold_{Low};
setting the B_{Low}=the B_{Low}+1 if the second voltage is less than the Threshold_{Low};
setting the brake=the brake+1 if the first voltage is less than the Threshold_{Low} and the second voltage is less than the Threshold_{Low};
setting the A_{Low_}B_{Fall}=the A_{Low_}B_{Fall}+1 if the first voltage is less that the Threshold_{Low} and the second voltage−the previous second voltage is less than or equal to zero;
setting the A_{Low_}B_{Rise}=the A_{Low_}B_{Rise}+1 if the first voltage is less that the Threshold_{Low} and the second voltage−the previous second voltage is greater than zero;
setting the B_{Low_}A_{Fall}=the B_{Low_}A_{Fall}+1 if the second voltage is less that the Threshold_{Low} and the first voltage−the previous first voltage is less than or equal to zero;
setting the B_{Low_}A_{Rise}=the B_{Low_}A_{Rise}+1 if the second voltage is less that the Threshold_{Low} and the first voltage−the previous first voltage is greater than zero;
setting the previous first voltage equal to the first voltage; and
setting the previous second voltage equal to the second voltage;
wherein when the electric motor is the brushed motor, the extracting state variables from the first voltage and the second voltage further comprises:
setting the N=the N+1;
setting the Fwd=the Fwd+1 if the first voltage minus the second voltage is greater than or equal to a Threshold_{Positive};
setting the Rev=the Rev+1 if the first voltage minus the second voltage is greater than or equal to a Threshold_{Negative};
setting the Idle=the Idle+1 if the first voltage and the second voltage are within a range of a Threshold_{IdleLow} and a Threshold_{IdleHigh}; and
setting the brake=the brake+1 if the first voltage is less than a Threshold_{Low} and the second voltage is less than the Threshold_{Low}.

4. The method according to claim 3 wherein the determining the tentative state comprises:
wherein when the electric motor is the brushless motor, the determining the tentative state further comprises:
setting a tentative state equal to the neutral state if the brake is less than or equal to a Threshold_{Brake} and the A_{Low_}B_{Fall} and the A_{Low_}B_{Rise} and the B_{Low_}A_{Fall} and the B_{Low_}A_{Rise} are each lower than a Threshold_{Move};
setting the tentative state equal to a brake state if the brake is greater than the Threshold_{Brake};
setting the tentative state equal to a forward state if the A_{Low_}B_{Fall} is greater than both the A_{Low_}B_{Rise} and the Threshold_{Move} or if the B_{Low_}A_{Fall} is greater than both the B_{Low_}A_{Rise} and the Threshold_{Move};
setting the tentative state equal to a reverse state if the A_{Low_}B_{Rise} is greater than both the A_{Low_}B_{Fall} and the Threshold_{Move} or if the B_{Low_}A_{Rise} is greater than both the B_{Low_}A_{Fall} and the Threshold_{Move};
setting the tentative state equal to a neutral moving state if the first and the second voltages are each greater than the Threshold_{Move} and the first voltage is not equal to the second voltage; and
setting the previous tentative state equal to the tentative state;
wherein when the electric motor is the brushed motor, the determining the tentative state comprises:
normalizing the Fwd, the Rev, the Idle, and the brake by dividing each of them by the N, respectively providing normalized Fwd, normalized Rev, normalized Idle, and normalized Brake;
setting the tentative state equal to the neutral state if the normalized Idle is greater than a Threshold_{Idle};
setting the tentative state equal to the forward state if the normalized Fwd is greater than a maximum of each of the normalized Rev, the normalized brake, and the normalized Idle; and
setting the tentative state equal to the reverse state if the normalized Rev is greater than a maximum of each of the normalized Fwd, the normalized brake, and the normalized Idle.

5. The method according to claim 4, wherein actuating the model vehicle component comprises:
illuminating a brake light when the model vehicle state is equal to the brake state, wherein the model vehicle component is the brake light;
illuminating a reverse light when the model vehicle state is the reverse state, wherein the model vehicle component is the reverse light;
illuminating the brake light and the reverse light when the model vehicle state is the brake state and the previous model vehicle state is reverse, wherein the model vehicle component comprises the reverse light and the brake light;
extinguishing the reverse light and the brake light when the model vehicle state is in the neutral state or the forward state, wherein the model vehicle component comprises the reverse light and the brake light; and
setting the previous model vehicle state equal to the model vehicle state.

6. The method according to claim 5, wherein actuating the model vehicle component additionally comprises actuating an acoustic device to generate engine sounds according to the model vehicle state.

7. A method of determining a state of a model vehicle using a brushless motor, comprising:
initializing variables;
setting a sample time equal to zero;
measuring raw variables comprising:
determining a first voltage relative to a battery ground; and
determining a second voltage relative to a battery ground;
extracting state variables from the first voltage and the second voltage;
setting the sample time equal to the sample time+an elapsed time;
returning to the action of the measuring of the raw variables if the sample time is less than or equal to a sample period duration;
determining a tentative state from the state variables if the sample time is greater than the sample period duration;
setting a model vehicle state equal to the tentative state if the tentative state is equal to a previous tentative state and actuating a model vehicle component corresponding to the model vehicle state;
setting a previous tentative state equal to the tentative state; and
returning to the action of the setting the sample time equal to zero.

8. The method according to claim 7, wherein the initializing variables action comprises:
setting a previous model vehicle state equal to a neutral state. setting the previous tentative state equal to the neutral state;
setting a previous first voltage equal to zero;
setting a previous second voltage equal to zero;
setting A_{Low} equal to zero;
setting B_{Low} equal to zero;
setting Brake equal to zero;
setting A_{Low_}B_{Fall} equal to zero;
setting A_{Low_}B_{Rise} equal to zero;
setting B_{Low_}A_{Fall} equal to zero; and
setting B_{Low_}A_{Rise} equal to zero.

9. The method according to claim 8, wherein the extracting state variables from the first voltage and the second voltage comprises:
setting the A_{Low}=the A_{Low}+1 if the first voltage is less than a Threshold_{Low};
setting the B_{Low}=the B_{Low}+1 if the second voltage is less than the Threshold_{Low};
setting brake=brake+1 if the first voltage is less than the Threshold_{Low} and the second voltage is less than the Threshold_{Low};
setting the A_{Low_}B_{Fall}=the A_{Low_}B_{Fall}+1 if the first voltage is less that the Threshold_{Low} and the second voltage−the previous second voltage is less than or equal to zero;
setting the A_{Low_}B_{Rise}=the A_{Low_}B_{Rise}+1 if the first voltage is less that the Threshold_{Low} and the second voltage−the previous second voltage is greater than zero;
setting the B_{Low_}A_{Fall}=the B_{Low_}A_{Fall}+1 if the second voltage is less that the Threshold_{Low} and the first voltage−the previous first voltage is less than or equal to zero;
setting the B_{Low_}A_{Rise}=the B_{Low_}A_{Rise}+1 if the second voltage is less that the Threshold_{Low} and the first voltage−the previous first voltage is greater than zero;
setting the previous first voltage equal to the first voltage; and
setting the previous second voltage equal to the second voltage.

10. The method according to claim 9 wherein the determining the tentative state comprises:
setting the tentative state equal to the neutral state if the brake is less than or equal to a Threshold_{Brake} and the A_{Low_}B_{Fall} and the A_{Low_}B_{Rise} and the B_{Low_}A_{Fall} and the B_{Low_}A_{Rise} are each lower than a Threshold_{Move};
setting the tentative state equal to a brake state if the brake is greater than the Threshold_{Brake};
setting the tentative state equal to a forward state if the A_{Low_}B_{Fall} is greater than both the A_{Low_}B_{Rise} and the Threshold_{Move} or if the B_{Low_}A_{Fall} is greater than both the B_{Low_}A_{Rise} and the Threshold_{Move};
setting the tentative state equal to a reverse state if the A_{Low_}B_{Rise} is greater than both the A_{Low_}B_{Fall} and the Threshold_{Move} or if the B_{Low_}A_{Rise} is greater than both the B_{Low_}A_{Fall} and the Threshold_{Move}; and
setting the tentative state equal to a neutral moving state if the first and the second voltages are each greater than the Threshold_{Move} and the first voltage is not equal to the second voltage.

11. The method according to claim 10, wherein actuating the model vehicle component comprises:
illuminating a brake light when the model vehicle state is equal to the brake state, wherein the model vehicle component is the brake light;
illuminating a reverse light when the model vehicle state is the reverse state, wherein the model vehicle component is the reverse light;
illuminating the brake light when the model vehicle state is the brake state and the previous model vehicle state is the reverse state, wherein the model vehicle component comprises the reverse light and the brake light;
extinguishing the reverse light and the brake like when the model vehicle state is neutral state or forward state, wherein the model vehicle component comprises the reverse light and the brake light; and
setting the previous model vehicle state equal to the model vehicle state.

12. The method according to claim 11, wherein actuating the model vehicle component additionally comprises actuating an acoustic device to generate engine sounds corresponding to the model vehicle state.

13. A method of determining a state of a model vehicle using a brushed motor, comprising:
initializing variables;
setting a sample time equal to zero;
measuring raw variables comprising:
determining a first voltage relative to a battery ground; and
determining a second voltage relative to a battery ground;
extracting state variables from the first voltage and the second voltage;
setting the sample time equal to the sample time+an elapsed time;
returning to the action of the measuring of the raw variables if the sample time is less than or equal to a sample period duration;
determining a tentative state from the state variables if the sample time is greater than the sample period duration;
setting a model vehicle state equal to the tentative state if the tentative state is equal to a previous tentative state, and actuating a model vehicle component corresponding to the model vehicle state;
setting the previous tentative state equal to the tentative state; and
returning to the action of the setting the sample time equal to zero.

14. The method according to claim 13, wherein the initializing variables action comprises:
setting a previous model vehicle state equal to a neutral state.
setting the previous tentative state equal to the neutral state;
setting N equal to zero;
setting Fwd equal to zero;
setting Rev equal to zero;
setting Idle equal to zero;
setting brake equal to zero;

15. The method according to claim 14, wherein the extracting state variables from the first voltage and the second voltage comprises:
setting the N=the N+1;
setting the Fwd=the Fwd+1 if the first voltage minus the second voltage is greater than or equal to a Threshold_{Positive};
setting the Rev=the Rev+1 if the first voltage minus the second voltage is greater than or equal to a Threshold_{Negative};
setting the Idle=the Idle+1 if the first voltage and the second voltage are within a range comprising from a Threshold_{IdleLow} to a Threshold_{IdleHigh};
setting the brake=the brake+1 if the first voltage is less than a Threshold_{Low} and the second voltage is less than the Threshold_{Low}.

16. The method according to claim 15 wherein the determining the tentative state comprises:
normalizing the Fwd, the Rev, the Idle, and the brake by dividing each of them by the N, respectively providing a normalized Fwd, a normalized Rev, a normalized Idle, and a normalized Brake;
setting the tentative state equal to the neutral state if the normalized Idle is greater than a Threshold_{Idle};
setting the tentative state equal to a forward state if the normalized Fwd is greater than a maximum of each of the normalized Rev, normalized brake, and normalized Idle;
setting the tentative state equal to a reverse state if the normalized Rev is greater than a maximum of each of the normalized Fwd, the normalized brake, and the normalized Idle; and
setting the tentative state equal to a brake state if the normalized brake is greater than a maximum of each of the normalized Fwd, the normalized Rev, and the normalized Idle.

17. The method according to claim 16, wherein actuating the model vehicle component comprises:
illuminating a brake light when the model vehicle state is equal to the brake state, wherein the model vehicle component is the brake light;
illuminating a reverse light when the model vehicle state is the reverse state, wherein the model vehicle component is the reverse light;
extinguishing the reverse light or the brake like when the model vehicle state is the neutral state or the forward state; and
setting the previous model vehicle state equal to the model vehicle state.

18. The method according to claim 17, wherein actuating the model vehicle component additionally comprises actuating an acoustic device to generate engine sounds according to the model vehicle state.
